(19) United States
(12) Patent Application Publication
(10) Pub. No.: US 2026/0006787 A1
(43) Pub. Date: Jan. 1, 2026

(54) SEMICONDUCTOR DEVICE WITH BOUND CHARGE LAYER AND ELECTRONIC SYSTEM INCLUDING THE SAME

(71) Applicant: SAMSUNG ELECTRONICS CO., LTD., Suwon-si (KR)

(72) Inventors: Jaewoo PARK, Suwon-si (KR); Ji-Sung KIM, Suwon-si (KR); Jun-Noh LEE, Suwon-si (KR); Chang-Soo LEE, Suwon-si (KR); Haeyeon JUN, Suwon-si (KR)

(73) Assignee: SAMSUNG ELECTRONICS CO., LTD., Suwon-si (KR)

(21) Appl. No.: 19/011,065

(22) Filed: Jan. 6, 2025

(30) Foreign Application Priority Data
Jun. 28, 2024 (KR) 10-2024-0085728

(51) Int. Cl. H10B 43/27; H01L 25/07; H10B 43/35; H10B 43/40; H10B 51/20; H10B 51/40; H10B 80/00

(52) U.S. Cl. CPC H10B 43/27; H01L 25/074; H10B 43/35; H10B 43/40; H10B 51/20; H10B 51/40; H10B 80/00; H01L 2225/06506

(57) ABSTRACT

A semiconductor device includes a substrate, a gate stacking structure, and a channel structure. The gate stacking structure includes a plurality of interlayer insulating layers and a plurality of gate electrodes alternately stacked on the substrate. The channel structure at least partially penetrates the gate stacking structure and extends in one direction. The channel structure includes a channel layer coupled with the substrate, a ferroelectric layer at least partially surrounding the channel layer and including a ferroelectric material, and a bound charge layer at least partially surrounding the ferroelectric material and including an insulating material. At least one of a conduction band energy level or a valence band energy level of the insulating material is disposed between a conduction band energy level and a valence band energy level of the ferroelectric material.

### CROSS-REFERENCE TO RELATED APPLICATIONS

This application claims benefit of priority under 35 U.S.C. § 119 to Korean Patent Application No. 10-2024-0085728, filed on Jun. 28, 2024, in the Korean Intellectual Property Office, the disclosure of which is incorporated by reference herein in its entirety.

### BACKGROUND

### 1. Field

The present disclosure relates generally to semiconductor devices, and more particularly, to a semiconductor device with a bound charge layer and an electronic system including the same.

### 2. Description of Related Art

Semiconductor memory devices may be classified into volatile memory devices and a nonvolatile memory devices. The volatile memory devices may refer to memory devices in which stored data may be lost when a power supply is cut off, such as, but not limited to, dynamic random access memory (DRAM), static random access memory (SRAM), or the like. The nonvolatile memory devices may refer to memory devices in which stored data may not be lost even when the power supply is cut off, such as, but not limited to, programmable read-only memory (PROM), erasable PROM (EPROM), electrically EPROM (EEPROM), flash memory devices, or the like. In addition, in line with recent trends toward increasing performance and reducing electric power of the semiconductor memory devices, next generation semiconductor memory devices with nonvolatile properties such as, but not limited to, magnetic random access memory (MRAM), phase-change random access memory (PRAM), or ferroelectric random access memory (FeRAM) may be being developed. As higher integration levels and/or higher performance of semiconductor devices may be demanded, various studies may be being conducted using semiconductor devices with different characteristics.

### SUMMARY

One or more example embodiments of the present disclosure provide a semiconductor device with improved reliability, when compared to related semiconductor devices, and an electronic system including the same.

According to an aspect of the present disclosure, a semiconductor device includes a substrate, a gate stacking structure, and a channel structure. The gate stacking structure includes a plurality of interlayer insulating layers and a plurality of gate electrodes alternately stacked on the substrate. The channel structure at least partially penetrates the gate stacking structure and extends in one direction. The channel structure includes a channel layer coupled with the substrate, a ferroelectric layer at least partially surrounding the channel layer and including a ferroelectric material, and a bound charge layer at least partially surrounding the ferroelectric material and including an insulating material. At least one of a conduction band energy level or a valence band energy level of the insulating material is disposed between a conduction band energy level and a valence band energy level of the ferroelectric material.

According to an aspect of the present disclosure, a semiconductor device includes a substrate, a gate stacking structure, and a channel structure. The gate stacking structure includes a plurality of interlayer insulating layers and a plurality of gate electrodes alternately stacked on the substrate. The channel structure at least partially penetrates the gate stacking structure and extends in one direction. The channel structure includes a channel layer coupled with the substrate, a ferroelectric layer at least partially surrounding the channel layer and including a ferroelectric material, and a bound charge layer at least partially surrounding the ferroelectric material and including an insulating material. A side surface of the bound charge layer is in contact with the ferroelectric layer. The bound charge layer includes a plurality of charges bound to a region adjacent to an interface with the ferroelectric layer.

According to an aspect of the present disclosure, an electronic system includes a main substrate, a semiconductor device on the main substrate, and a controller electrically coupled with the semiconductor device on the main substrate. The semiconductor device includes a peripheral circuit region, a cell region including an input/output connection wire electrically coupled with the peripheral circuit region, and an input/output pad electrically coupled with the input/output connection wire extending into the cell region. The cell region includes a substrate, a gate stacking structure, and a channel structure. The gate stacking structure includes a plurality of interlayer insulating layers and a plurality of gate electrodes alternately stacked on the substrate. The channel structure at least partially penetrates the gate stacking structure and extends in one direction. The channel structure includes a channel layer coupled with the substrate, a ferroelectric layer at least partially surrounding the channel layer and including a ferroelectric material, and a bound charge layer at least partially surrounding the ferroelectric material and including an insulating material. At least one of a conduction band energy level or a valence band energy level of the insulating material is disposed between a conduction band energy level and a valence band energy level of the ferroelectric material.

Aspects of the present disclosure provide a semiconductor that includes a bound charge layer that is disposed between the ferroelectric layer and the gate electrode and includes a plurality of bound charges.

According to aspects of the present disclosure, the bound charges may effectively compensate for polarization charges at the interface between the ferroelectric layer and the bound charge layer, and accordingly, may reduce depolarization in the ferroelectric layer and may improve the reliability of semiconductor devices, when compared to related semiconductor devices.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIGS. 1 and 2 are cross-sectional views of a semiconductor device, according to an embodiment;

FIGS. 3 and 4 are cross-sectional views of various examples of a channel structure included in the semiconductor device shown in FIG. 1, according to an embodiment;

FIG. 5 is an enlarged cross-sectional view of the region A of FIG. 2, according to an embodiment;

FIG. 6 is an enlarged cross-sectional view of the region B of FIG. 5, according to an embodiment;

FIG. 7 is an energy band diagram illustrating energy bands according to position in the region B of FIG. 5, according to an embodiment;

FIG. 8 is an energy band diagram depicting energy bands according to position of the bound charge layer and the ferroelectric layer, according to an embodiment;

FIG. 9 shows a comparison between the energy bandgap of insulating materials and the energy bandgap of ferroelectric materials, according to an embodiment;

FIG. 10 schematically shows an electronic system including a semiconductor device, according to an embodiment;

FIG. 11 is a schematic perspective view of the electronic system including a semiconductor, according to an embodiment; and

FIGS. 12 and 13 are schematic cross-sectional views of semiconductor packages, according to an embodiment.

### DETAILED DESCRIPTION

Hereinafter, various embodiments of the present disclosure are described with reference to the attached drawings such that a person having ordinary skill in the art to which the present disclosure pertains may implement the invention. The present disclosure may be implemented in many different forms and may not be limited to the embodiments described herein.

The drawings and the description are to be regarded as illustrative in nature and not restrictive. Like reference numerals may designate like elements throughout the specification.

Since the size and thickness of each configuration shown in the drawings may be arbitrarily indicated for better understanding and ease of description, the present disclosure is not necessarily limited to the drawings. In the drawings, the thickness of layers, films, panels, regions, or the like, may be exaggerated for clarity, better understanding, and ease of description.

It is to be understood that when an element such as a layer, film, region, or substrate is referred to as being “on” another element, the element may be directly on the other element or intervening elements may also be present. Alternatively or additionally, when an element is referred to as being “directly on” another element, there may be no intervening elements present. Further, throughout the specification, the term “on” a target element is to be understood to refer to the target element being positioned above or below the target element, and may not be necessarily be understood to mean positioned “at an upper side” based on direction that may be opposite to gravity.

Unless explicitly described to the contrary, the term “comprise”, and/or variations such as, but not limited to, “comprises” or “comprising”, are to be understood to imply the inclusion of stated elements but not the exclusion of any other elements.

It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, or the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, or the like may be used to distinguish components from each other and do not limit the present disclosure. For example, the terms “first”, “second”, “third”, or the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, or the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

As used herein, each of the terms “Al₂O₃”, “AlON”, “AlScN”, “BaTiO₃”, “BaZrO₃”, “Ga₂O₃”, “HfO₂”, “HfON”, “HfSiO”, “HfSiON”, “HfTaO”, “HfTiO₄”, “HfZnO”, “HfₓZr₁₋ₓO₂”, “La₂O₃”, “PbTiO₃”, “PbZrₓTi₁₋ₓO₃”, “SiNₓ”, “SiO₂”, “SiON”, “TaN”, “Ta₂O₅”, “TiN”, “Y₂O₃”, or the like may refer to a material made of elements included in each of the terms and is not a chemical formula representing a stoichiometric relationship.

Throughout the specification, the phrase “on a plane” may refer to viewing a target portion from the top, and the phrase “on a cross-section” may refer to viewing a cross-section formed by vertically cutting a target portion from the side.

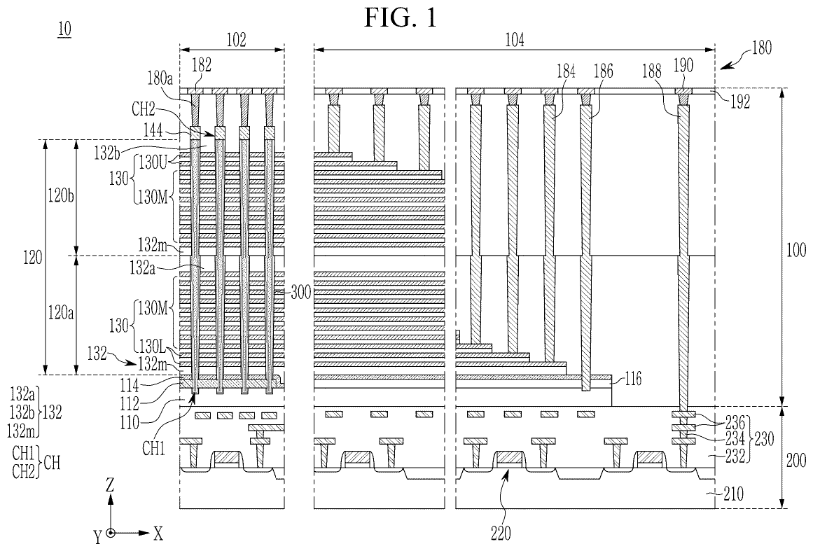

Hereinafter, referring to FIGS. 1 to 13, a semiconductor device according to an embodiment is described.

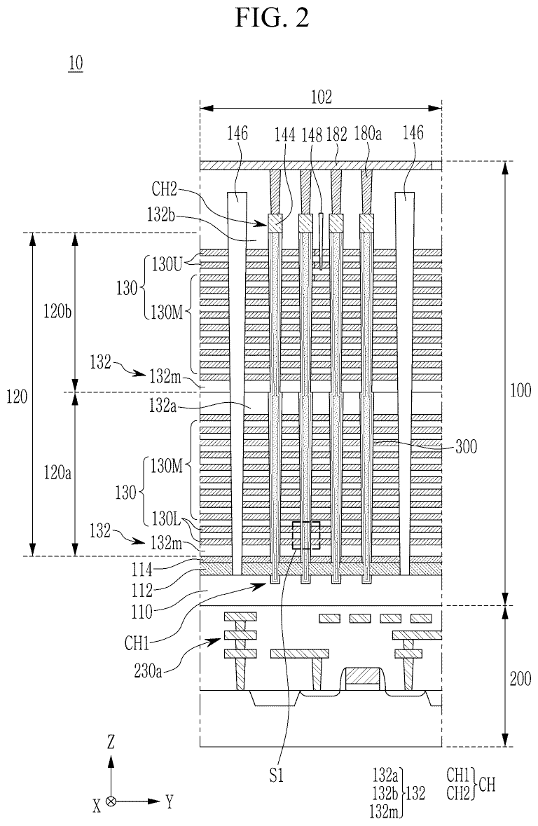

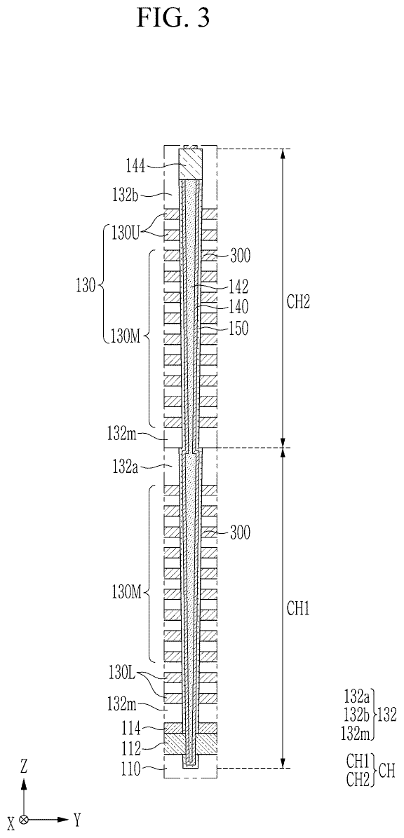

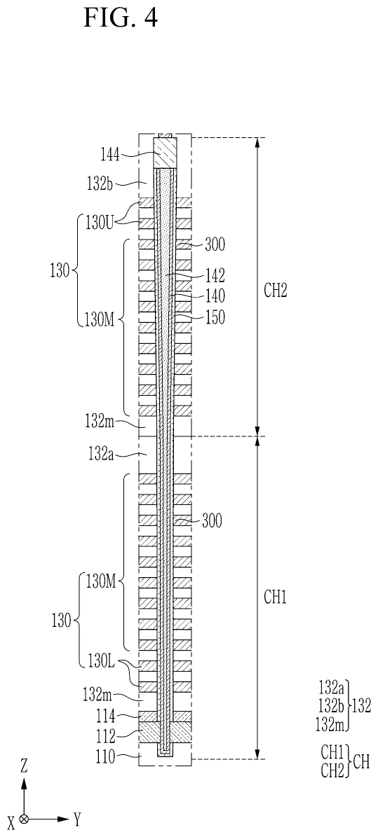

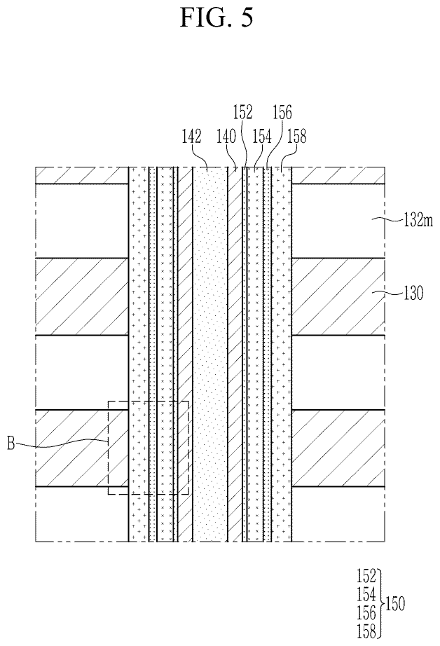

FIGS. 1 and 2 are cross-sectional views of a semiconductor device, according to an embodiment. FIGS. 3 and 4 are cross-sectional views of various examples of a channel structure included in the semiconductor device shown in FIG. 1, according to an embodiment. FIG. 5 is an enlarged cross-sectional view of the region A of FIG. 2, according to an embodiment.

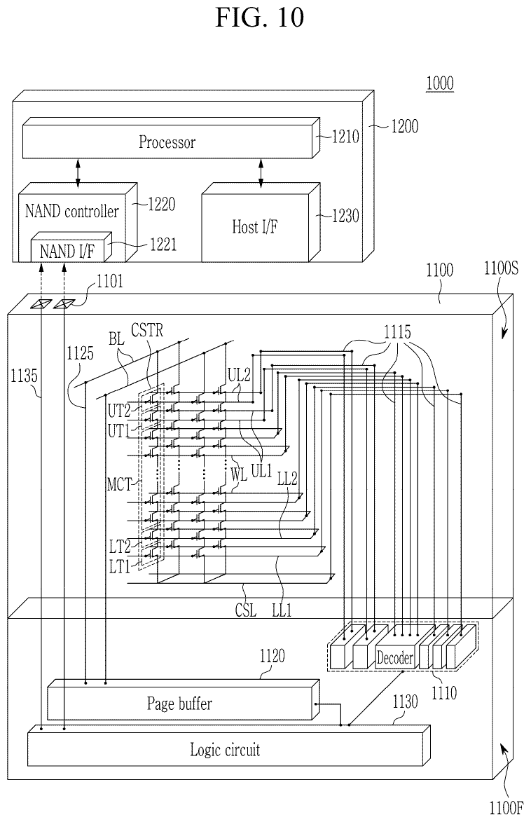

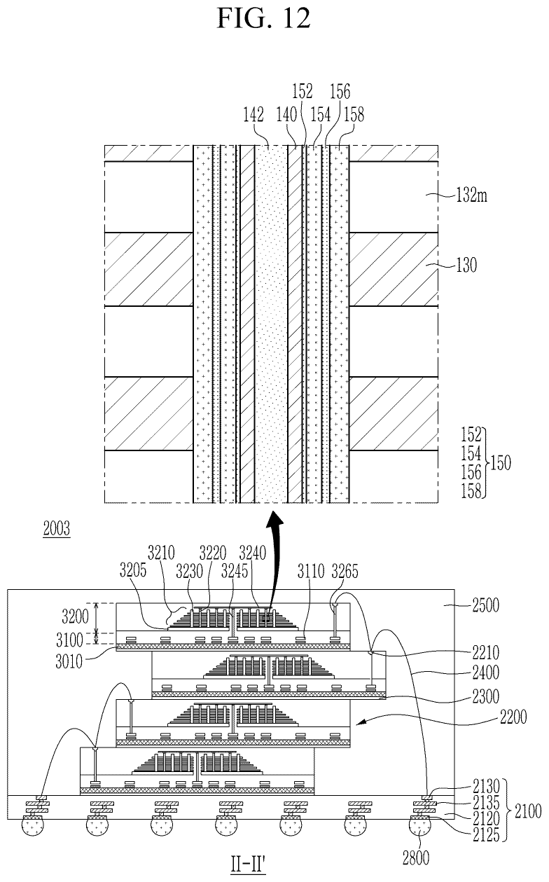

Referring to FIGS. 1 and 2, a semiconductor device 10, according to an embodiment, may include a cell region 100 provided with a memory cell structure and a circuit region 200 provided with a peripheral circuit structure for controlling operation of the memory cell structure. For example, the circuit region 200 and the cell region 100 may be and/or may include regions respectively corresponding to a first structure 1100F and a second structure 1100S described with reference to FIG. 10. Alternatively or additionally, the circuit region 200 and the cell region 100 may be and/or may include portions respectively corresponding to a first structure 3100 and a second structure 3200 described with reference to FIG. 12.

In an embodiment, the cell region 100 may be disposed on the circuit region 200. Consequently, an area corresponding to the circuit region 200 may not need to be secured separately from the cell region 100, and as a result the area of semiconductor device 10 may be reduced, when compared to a related semiconductor device. However, the present disclosure is not limited in this regard. For example, the circuit region 200 may be disposed adjacent to the cell region 100.

The cell region 100 may include a cell array region 102 and a contact region 104 disposed on a second substrate 110. The cell array region 102 may include a memory cell structure including a plurality of memory cells. The contact region 104 may include electrodes for electrically connecting the memory cells to other circuit components (e.g., circuit elements 220 included in circuit region 200), and/or to an external circuit.

In an embodiment, the cell array region 102 may include a gate stacking structure 120 and a channel structure CH disposed on a first surface (e.g., a front surface or top surface) of the second substrate 110. The channel structure CH may include a channel layer 140 that may penetrate the gate stacking structure 120 and may be connected to the second substrate 110, a ferroelectric layer 154 surrounding the channel layer 140, and a bound charge layer 156 surrounding the ferroelectric layer 154.

The second substrate 110 may include a semiconductor material (e.g., polysilicon). For example, the second substrate 110 may include impurity-doped polysilicon. However, the present disclosure is not limited in this regard. For example, the second substrate 110 may include a metallic material and/or a metal silicide. The gate stacking structure 120 in which a cell insulation layer 132 and a plurality of gate electrodes 130 are alternately stacked may be disposed on the second substrate 110.

In an embodiment, the gate stacking structure 120 may include a plurality of gate stacking structures (e.g., a first gate stacking structure 120a and a second gate stacking structure 120b) that may be sequentially stacked on the second substrate 110 and respectively including a cell insulation layer 132 and a plurality of gate electrodes 130 that are alternately stacked. In such a case, the number of the plurality stacked of gate electrodes 130 may be increased, thereby increasing the number of memory cells with a stable structure. For example, the gate stacking structure 120 may include the first gate stacking structure 120a and the second gate stacking structure 120b, thereby simplifying the structure while increasing data storage capacity. However, the present disclosure is not limited thereto. For example, the gate stacking structure 120 may be formed of one (1) gate stacking structure or may include three (3) or more gate stacking structures.

In the gate stacking structure 120, the plurality of gate electrodes 130 may include a lower gate electrode 130L, a memory cell gate electrode 130M, and an upper gate electrode 130U sequentially disposed from the second substrate 110. The lower gate electrode 130L may be used as a gate electrode of a ground selection transistor, the memory cell gate electrode 130M may form a memory cell, and the upper gate electrode 130U may be used as a gate electrode of a string selection transistor. The number of memory cell gate electrodes 130M may be determined depending on the data storage capacity of the semiconductor device 10. Depending on embodiments, the lower gate electrode 130L and the upper gate electrode 130U may each be provided with one (1), two (2), or more cell gate electrodes, and/or may have the same structure as the memory cell gate electrode 130M or a different structure. In addition, a portion of the plurality of gate electrodes 130 (e.g., the memory cell gate electrode 130M adjacent to the lower gate electrode 130L and the upper gate electrode 130U) may be a dummy gate electrode.

The cell insulation layer 132 may include a plurality of interlayer insulating layers 132m disposed below the plurality of gate electrodes 130 or between two (2) adjacent gate electrodes 130 in the first gate stacking structure 120a and the second gate stacking structure 120b and upper insulation layers (e.g., a first upper insulation layer 132a and a second upper insulation layer 132b) disposed above the first gate stacking structure 120a and the second gate stacking structure 120b. For example, the first and second upper insulation layers 132a and 132b may include a first upper insulation layer 132a disposed on an upper portion of the first gate stacking structure 120a, and a second upper insulation layer 132b disposed on an upper portion of the second gate stacking structure 120b. In such a case, the first upper insulation layer 132a may be an intermediate insulation layer disposed between the first gate stacking structure 120a and the second gate stacking structure 120b, and the second upper insulation layer 132b may be and/or may include an uppermost insulation layer disposed at the top of the gate stacking structure 120. The second upper insulation layer 132b may form a part or all of a cell region insulation layer disposed entirely above the cell region 100. In the embodiment, thicknesses of the plurality of cell insulation layers 132 may not all be the same (e.g., may be varied). For example, thicknesses of upper insulation layers 132a and 132b may be greater than a thickness of the plurality of interlayer insulating layers 132m. However, the shape, structure, or the like of the cell insulation layer 132 may vary depending on the embodiment.

Although FIGS. 1 to 4 illustrate that the cell insulation layer 132 has a boundary between first gate stacking structure 120a and second gate stacking structure 120b in a contact region 104, the present disclosure is not limited thereto. In the contact region 104, a plurality of insulation layers may have various stacking structures and the present disclosure is not limited thereto.

The plurality of gate electrodes 130 may include various conductive materials. For example, the plurality of gate electrodes 130 may include a metallic material such as, but not limited to, tungsten (W), copper (Cu), aluminum (Al), or the like. As another example, the plurality of gate electrodes 130 may include, but not limited to, a polysilicon, a metal nitride (e.g., titanium nitride (TiN), tantalum nitride (TaN)), and/or a combination thereof. An insulation layer formed of an insulating material may be disposed on the outside of the plurality of gate electrodes 130, or a portion of a dielectric layer 150 may be disposed. The cell insulation layer 132 may include various insulating materials. For example, the cell insulation layer 132 may include, but not be limited to, silicon oxide (SiO₂), silicon nitride (SiNₓ), silicon oxynitride (SiON), a low dielectric constant material, and/or a combination thereof having a lower permittivity than silicon oxide (SiO₂).

The channel structure CH may extend in a direction (e.g., a third direction (Z-axis direction)) that may penetrate the gate stacking structure 120 and may intersect the second substrate 110. Referring to FIGS. 3 to 5, the channel structure CH of the semiconductor device, according to an embodiment, may include a channel layer 140 and a dielectric layer 150 disposed on the channel layer 140 between the plurality of gate electrode 130 and the channel layer 140. The channel structure CH may further include a core insulation layer 142 disposed in the channel layer 140, and may further include a channel pad 144 disposed on the channel layer 140 and/or the dielectric layer 150.

Each channel structure CH may form a memory cell string, and a plurality of channel structures CH may be arranged spaced apart from each other in rows and columns on a plane. For example, on the plane, the plurality of channel structures CH may be arranged in various shapes, such as, but not limited to, a lattice shape, a zigzag shape, or the like.

In an embodiment, the channel structure CH may have a columnar shape. For example, the channel structure CH may have an inclined side surface such that a width becomes narrower as the channel structure CH approaches the second substrate 110 according to the aspect ratio when viewed in cross-section. However, the present disclosure is not limited in this regard. For example, the arrangement, structure, shape, or the like of the channel structure CH may be changed in various ways without departing from the scope of the present disclosure.

The core insulation layer 142 may be provided in a central region of the channel structure CH, and the channel layer 140 may be disposed while surrounding a sidewall of the core insulation layer 142. That is, the channel layer 140 may surround the core insulation layer 142. For example, the core insulation layer 142 may have a columnar shape (e.g., a circular cylinder shape, a polygonal column shape, or the like), and the channel layer 140 may have a planar shape such as, but not limited, an annular shape. However, the present disclosure is not limited in this regard. For example, the core insulation layer 142 may not be provided and the channel layer 140 may have a columnar shape (e.g., a circular cylinder shape, a polygonal column shape, or the like).

The channel layer 140 may penetrate a first horizontal conductive layer 112 and a second horizontal conductive layer 114. The channel layer 140 may be electrically connected with the first and second horizontal conductive layers 112 and 114. For example, a part of a side surface of the channel layer 140 may directly contact a side surface of the first horizontal conductive layer 112, and thus may be electrically connected thereto.

The channel layer 140 may include a semiconductor material, for example, a polysilicon, or the like. The core insulation layer 142 may include various insulating materials. For example, the core insulation layer 142 may include, but not be limited to, silicon oxide (SiO₂), silicon nitride (SiNₓ), silicon oxynitride (SiON), and/or a combination thereof. However, the materials of the channel layer 140 and the core insulation layer 142 are not limited thereto.

In the embodiment, the dielectric layer 150 may include a ferroelectric layer 154 disposed outside the channel layer 140 and a bound charge layer 156 disposed outside the ferroelectric layer 154. The ferroelectric layer 154 may surround the channel layer 140, and the bound charge layer 156 may surround the ferroelectric layer 154. In the embodiment, the dielectric layer 150 may further include a channel insulation layer 152 disposed between the channel layer 140 and the ferroelectric layer 154 and a tunneling insulation layer 158 disposed between the bound charge layer 156 and the gate electrode 130. In the embodiment, the channel insulation layer 152, the ferroelectric layer 154, the bound charge layer 156, and the tunneling insulation layer 158 may be sequentially stacked on an exterior side of the channel layer 140.

The channel insulation layer 152 may surround the channel layer 140. For example, the channel insulation layer 152 may extend in the third direction (Z direction), and thus may surround the side surface of the channel layer 140.

The channel insulation layer 152 may have a planar shape such as, but not limited to, an annular shape.

The channel insulation layer 152 may include an insulating material. For example, the channel insulation layer 152 may include at least one of silicon oxide (SiO₂), silicon oxynitride (SiON), aluminum oxynitride (AlON), hafnium oxynitride (HfON), aluminum oxide (Al₂O₃), and carbon (C) doped silicon oxide (SiO₂). Alternatively or additionally, the channel insulation layer 152 may include a high dielectric constant (high-k) material having a higher dielectric constant than silicon oxide (SiO₂). For example, the channel insulation layer 152 may include at least one of hafnium oxide (HfO₂), hafnium zirconium oxide (HfₓZr₁₋ₓO₂), barium titanium oxide (BaTiO₃), and aluminum scandium nitride (AlScN) doped with at least one of silicon (Si), aluminum (Al), yttrium (Y), strontium (Sr), gadolinium (Gd), or lanthanum (La). The channel insulation layer 152 may be formed by laminating, for example, a plurality of layers including the insulating materials listed above.

The ferroelectric layer 154 may surround the channel insulation layer 152. One side surface of the ferroelectric layer 154 may contact the channel insulation layer 152. In the embodiment, the semiconductor device 10 may not include the channel insulation layer 152. That is, the channel insulation layer 152 may be omitted from the dielectric layer 150, according to the embodiment. In such a case, one side of the ferroelectric layer 154 may be in contact with the channel layer 140.

In an embodiment, the ferroelectric layer 154 may overlap the gate electrode 130 and the channel structure CH in the radial direction. The ferroelectric layer 154 may overlap with the interlayer insulating layer 132m in the radial direction of the channel structure CH. For example, a part of the ferroelectric layer 154 may overlap the gate electrode 130 in the radial direction of the channel structure CH, and a remaining part of the ferroelectric layer 154 may overlap the plurality of interlayer insulating layers 132m in the radial direction of the channel structure CH. The ferroelectric layer 154 may include a ferroelectric material.

The ferroelectric layer 154 may include a hafnium (Hf) compound having ferroelectric characteristics. As an example, the ferroelectric layer 154 may include hafnium oxide (HfO₂), hafnium zinc oxide (HfZnO), hafnium silicon oxide (HfSiO), hafnium silicon oxynitride (HfSiON), hafnium tantalum oxide (HfTaO), hafnium titanate (HfTiO₄), hafnium zirconium oxide (HfₓZr₁₋ₓO₂), or a combination thereof. In addition, the ferroelectric layer 154 may include a ferroelectric material of a perovskite structure, such as, for example, PZT (PbZrₓTi₁₋ₓO₃), barium titanium oxide (BaTiO₃), lead titanate (PbTiO₃), or the like. The ferroelectric layer 154 may include a dopant, such as, but not limited to, at least one of carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), and lanthanum (La). The ferroelectric layer 154 may be made of a crystalline material. For example, the ferroelectric layer 154 may have a crystal structure of the orthorhombic system.

In an embodiment, when the ferroelectric layer 154 has ferroelectricity, the ferroelectric layer 154 may be configured to have various states of polarization depending on a voltage applied between the plurality of gate electrodes 130 and the channel layer 140. That is, a residual polarization may be generated within the ferroelectric layer 154 by the voltage applied between the plurality of gate electrodes 130 and the channel structure CH. The residual polarization may be a polarization that remains within the ferroelectric layer 154 after the electric field due to the voltage applied between the gate electrode 130 and the channel layer 140 disappears during the operation of the semiconductor device, according to the embodiment (e.g., program or erase operation). The size of the residual polarization generated within the ferroelectric layer 154 may be determined by a polarization-voltage (PV) hysteresis characteristic that may consider not only the magnitude of the voltage applied between the plurality of gate electrodes 130 and the channel layer 140 but also the process through which the residual polarization generated within the ferroelectric layer 154 has passed. The generated residual polarization may be stored within the ferroelectric layer 154, and signal information may be stored non-volatilized by the stored residual polarization. In an embodiment, the ferroelectric layer 154 may function as a non-volatile memory layer.

The bound charge layer 156 may surround the ferroelectric layer 154. The bound charge layer 156 may have an annulus shape on the plane. The bound charge layer 156 may be disposed between a ferroelectric layer 154 and a tunneling insulation layer 158. One side surface of the bound charge layer 156 may contact the ferroelectric layer 154. The other side surface of the bound charge layer 156 may contact the tunneling insulation layer 158. The bound charge layer 156 may include a plurality of bound charges that inflow into the bound charge layer 156 through the tunneling insulation layer 158 during a program or erase operation of the semiconductor device, according to the embodiment.

The bound charge layer 156 may include an insulating material. In the embodiment, the insulating material included in the bound charge layer 156 may be selected as a material in which the number of charge trap sites existing inside the bound charge layer 156 may be minimized. For example, the insulating material included in the bound charge layer 156 may be at least one of a ferroelectric material included in the ferroelectric layer 154 or a material having a relatively high conduction band offset and/or valence band offset.

The tunneling insulation layer 158 may surround the bound charge layer 156. The tunneling insulation layer 158 may be disposed between the gate electrode 130 and the bound charge layer 156. One side of the tunneling insulation layer 158 may be in contact with the bound charge layer 156, and the other side may be in contact with the gate electrode 130 between the gate electrode 130 and the bound charge layer 156. The tunneling insulation layer 158 may also be disposed between the interlayer insulating layer 130m and the bound charge layer 156. One side of the tunneling insulation layer 158 may contact the bound charge layer 156 and the other side may contact the interlayer insulating layer 130m between the interlayer insulating layer 130m and the bound charge layer 156. During a program or erase operation of the semiconductor device, electrons and/or holes may flow from the gate electrode 130 through the tunneling insulation layer 158 into the bound charge layer 156. After the electric field for a program or erase operation is removed, the tunneling insulation layer 158 may serve as a barrier to prevent electrons or holes that have inflowed into the bound charge layer 156 from escaping back to the gate electrode 130.

The tunneling insulation layer 158 may include an insulating material. The tunneling insulation layer 158 may include at least one of, for example, silicon oxide (SiO₂), silicon nitride (SiNₓ), or silicon oxynitride (SiON). Although FIG. 5 illustrates the tunneling insulation layer 158 as consisting of one (1) layer, the present disclosure is not limited in this regard. For example, the tunneling insulation layer 158 may consist of two (2) or more layers. As another example, the tunneling insulation layer 158 may consist of three (3) insulation layers. In such a case, the tunneling insulation layer 158 may be formed of two (2) layers each containing silicon oxide (SiO₂), and one (1) layer disposed between the two (2) layers and containing silicon nitride (SiNₓ). However, the present disclosure is not limited thereto, and the tunneling insulation layer 158 may be formed of a plurality of layers including at least one of silicon oxide (SiO₂), silicon nitride (SiNₓ), or silicon oxynitride (SiON).

The semiconductor device 10, according to the embodiment, may further include a channel pad 144 disposed on the channel layer 140 and/or the dielectric layer 150. The channel pad 144 may cover an upper surface of the core insulation layer 142. The channel pad 144 may be arranged to be electrically connected with the channel layer 140. Although FIGS. 1 to 4 illustrate the channel pad 144 as covering an upper surface of the dielectric layer 150, the present disclosure is not limited thereto. For example, the channel pad 144 may not cover the upper surface of the dielectric layer 150. In such a case, a side surface of the channel pad 144 may be covered by the dielectric layer 150. The side surface of the channel pad 144 may contact the cell insulation layer 132. The channel pad 144 may include a conductive material, for example, impurity-doped polysilicon. However, the material of the channel pad 144 is not limited thereto, and may be variously changed.

The semiconductor device 10, according to the embodiment, may further include a first horizontal conductive layer 112 and a second horizontal conductive layer 114 disposed between the second substrate 110 and the gate stacking structure 120, or between the second substrate 110 and the channel structure CH. In the cell array region 102, the first horizontal conductive layer 112 may be disposed on the second substrate 110. The first horizontal conductive layer 112 may electrically connect the channel structure CH and the second substrate 110. The first horizontal conductive layer 112 may serve as a part of a common source line of the semiconductor device 10 (e.g., CSL of FIG. 10). For example, the first horizontal conductive layer 112 may serve as the common source line with the second substrate 110.

The channel structure CH may penetrate the first horizontal conductive layer 112. In such a case, the ferroelectric layer 154 and the channel insulation layer 152 of the channel structure CH may be removed in a portion where the first horizontal conductive layer 112 is disposed such that the first horizontal conductive layer 112 may be connected with the channel layer 140. That is, the first horizontal conductive layer 112 may directly contact the channel layer 140. Accordingly, the first horizontal conductive layer 112 may electrically connect the second substrate 110 and the channel layer 140.

In some regions of the contact region 104, the first horizontal conductive layer 112 may not be provided between the second substrate 110 and the gate stacking structure 120. In such a case, a horizontal insulation layer 116 may be provided between the second substrate 110 and the gate stacking structure 120. The horizontal insulation layer 116 may include various insulating materials. For example, the horizontal insulation layer 116 may include, but not be limited to, silicon oxide (SiO₂) and/or silicon nitride (SiNₓ). The horizontal insulation layer 116 may be a material remaining in some region of the contact region 104 during a replacement process to form the first horizontal conductive layer 112. The horizontal insulation layer 116 may be formed of multiple layers, however, the present disclosure is not limited thereto.

The second horizontal conductive layer 114 may be disposed on the first horizontal conductive layer 112 and the horizontal insulation layer 116. The second horizontal conductive layer 114 may extend along the first direction (X direction) and the second direction (Y direction) in the cell array region 102 and the contact region 104. The second horizontal conductive layer 114 may electrically connect between the channel structure CH and the second substrate 110 together with the first horizontal conductive layer 112. The second horizontal conductive layer 114 may serve as a part of a common source line of the semiconductor device 10. The channel structure CH may penetrate the second horizontal conductive layer 114.

The second horizontal conductive layer 114 may be used as a support layer to prevent a mold stack from collapsing or tipping over during the replacement process to form the first horizontal conductive layer 112.

The first horizontal conductive layer 112 and the second horizontal conductive layer 114 may include a semiconductor material (e.g., polysilicon). For example, the first horizontal conductive layer 112 may include impurity-doped polysilicon, the second horizontal conductive layer 114 may include impurity-doped polysilicon or may be a layer including an impurity diffused from the first horizontal conductive layer 112. However, the present disclosure is not limited thereto and the second horizontal conductive layer 114 may also include an insulating material. Alternatively or additionally, the second horizontal conductive layer 114 may not be provided separately.

As described above, in the case where the gate stacking structure 120 includes a plurality of gate stacking structures 120a and 120b that are stacked on each other, the channel structure CH may be provided with a plurality of channel structures CH1 and CH2 that penetrate the plurality of gate stacking structures 120a and 120b, respectively. For example, when the plurality of gate stacking structure 120 includes a first gate stacking structure 120a and a second gate stacking structure 120b, the plurality of channel structures CH may include a first channel structure CH1 extending through the first gate stacking structure 120a, and a second channel structure CH2 extending through the second gate stacking structure 120b.

The first channel structure CH1 and the second channel structure CH2 may have a connected form. The first channel structure CH1 and the second channel structure CH2 may have inclined side surfaces such that widths become narrower as the channel structures get closer to the second substrate 110 according to the aspect ratio when viewed on a cross-section. As shown in FIG. 3, a bending portion may be formed due to a difference in width at a part where the first channel structure CH1 and the second channel structure CH2 are connected. As another example, as shown in FIG. 4, the first channel structure CH1 and the second channel structure CH2 may have inclined side surfaces that may be continuously connected without a bend. However, the shapes of the first channel structure CH1 and the second channel structure CH2 are not limited thereto and may be changed in various ways without departing from the scope of the present disclosure.

As shown in FIGS. 1 and 2, the dielectric layer 150, the channel layer 140, and the core insulation layer 142 of the first channel structure CH1 and the second channel structure CH2 may be extended to each other, thereby forming an integral structure. The above-described structure may be formed by forming the dielectric layer 150, the channel layer 140, and the core insulation layer 142 over the entire first and second through-hole portions after forming the first through-hole portion for the first channel structure CH1 and the second through-hole portion for the second channel structure CH2. However, the present disclosure is not limited thereto. As another example, the dielectric layer 150, the channel layer 140, and the core insulation layer 142 of the first channel structure CH1 and the second channel structure CH2 may be formed separately from each other and may be electrically connected to each other. For example, after forming the first through-hole portion for the first channel structure CH1, the dielectric layer 150, the channel layer 140, and the core insulation layer 142 may be formed in the first through-hole portion, and after forming the second through-hole portion for the second channel structure CH2, the dielectric layer 150, the channel layer 140, and the core insulation layer 142 may be formed in the second through-hole portion.

In an embodiment, the channel pad 144 may be provided on the channel structure CH (e.g., the second channel structure CH2) provided on the gate stacking structure 120 (e.g., the second gate stacking structure 120b) disposed at an upper position among the plurality of gate stacking structures 120. Alternatively or additionally, the channel pad 144 may be provided on each of the first channel structure CH1 and the second channel structure CH2. In such a case, the channel pad 144 of the first channel structure CH1 may be connected to the channel layer 140 of the second channel structure CH2.

In the embodiment, the gate stacking structure 120 may be partitioned into multiple parts on a plane by a separation structure 146 extending in a direction intersecting the second substrate 110 (e.g., third direction (Z direction)) and penetrating the gate stacking structure 120.

For example, the separation structure 146 may extend through the plurality of gate electrodes 130 and the cell insulation layer 132 to an upper surface of the second substrate 110. On a plane, the separation structure 146 may be provided in multiple numbers so as to extend in the first direction (X direction) and be spaced apart from each other by a predetermined distance in the second direction (Y direction) intersecting the first direction (X direction). Accordingly, on a plane, the plurality of gate stacking structures 120 may each extend in the first direction (X direction) and be spaced apart from each other by a predetermined interval in the second direction (Y direction). The gate stacking structure 120 partitioned by the separation structure 146 may form one memory cell block. However, the present disclosure is not limited in this regard, and the range of the memory cell blocks is not limited thereto.

For example, the separation structure 146 may have an inclined side surface with a width that may decrease toward the second substrate 110 when viewed on a cross-section due to its high aspect ratio. However, the present disclosure is not limited in this regard. For example, the side of the separation structure 146 may be perpendicular to the second substrate 110. On a cross-sectional view, as illustrated in FIG. 2, the separation structure 146 may have continuous inclined side surfaces and no bend portion in the first gate stacking structure 120a and the second gate stacking structure 120b. However, the present disclosure is not limited thereto, and the separation structure 146 may also have a bend at the boundary between the first gate stacking structure 120a and the second gate stacking structure 120b.

The separation structure 146 may be filled with various insulating materials. For example, the separation structure 146 may include an insulating material such as silicon oxide (SiO₂), silicon nitride (SiNₓ), or silicon oxynitride (SiON). However, the present disclosure is not limited in this regard. For example, the structure, shape, material, or the like of the separation structure 146 may be changed in various ways without departing from the scope of the present disclosure.

The semiconductor device, according to the embodiment, may further include an upper separation pattern 148. The upper separation pattern 148 may be disposed on the gate stacking structure 120. On a plane, the upper separation pattern 148 may be provided in multiples so as to extend in the first direction (X direction) and be spaced apart from each other by a predetermined distance in the second direction (Y direction).

The upper separation pattern 148 may be formed by penetrating one or the plurality of gate electrodes 130 including an upper gate electrode 130U disposed between the separation structures 146. The upper separation pattern 148 may separate, for example, two electrodes of a plurality of gate electrodes 130 in the second direction (Y direction). However, the number of electrodes of the plurality of gate electrodes 130 separated by the upper separation pattern 148 is not limited thereto and may be changed in various ways without departing from the scope of the present disclosure.

The upper separation pattern 148 may have a form filled with an insulating material. For example, the upper separation pattern may include an insulating material such as, but not limited to, silicon oxide (SiO₂), silicon nitride (SiNₓ), or silicon oxynitride (SiON). However, the present disclosure is not limited in this regard. For example, the structure, shape, material, or the like of the upper separation pattern 148 may be changed in various ways without departing from the scope of the present disclosure.

The circuit region 200 may include a first substrate 210, a circuit element 220 and a first wiring portion 230 disposed on the first substrate 210.

The first substrate 210 may be and/or may include a semiconductor substrate including a semiconductor material. For example, the first substrate 210 may be and/or may include a semiconductor substrate formed of a semiconductor material, and/or may be and/or may include a semiconductor substrate in which a semiconductor layer is formed on a base substrate. For example, the first substrate 210 may be formed of at least one of silicon (Si), epitaxial silicon, germanium (Ge), silicon-germanium (Si—Ge), silicon-on-insulator (SOI), germanium-on-insulator (GOI), or the like.

The circuit element 220 formed on the first substrate 210 may include various circuit elements that may control operation of a memory cell structure provided in the cell region 100. For example, the circuit element 220 may form a peripheral circuit structure such as, but not limited to, a decoder circuit (e.g., decoder circuit 1110 of FIG. 10), a page buffer (e.g., page buffer 1120 of FIG. 10), a logic circuit (e.g., logic circuit 1130 of FIG. 10), or the like.

The circuit element 220 may include, for example, a transistor, however, the present disclosure is not limited in this regard. For example, the circuit element 220 may include not only an active element such as, but not limited to, a transistor or the like but may also include a passive element such as, but not limited to, a capacitor, a resistor, an inductor, or the like.

The first wiring portion 230 disposed on the first substrate 210 may be electrically connected with the circuit element 220. In an embodiment, the first wiring portion 230 may include a plurality of wiring layers 236 that may be spaced from each other, while disposing the first insulation layer 232 therebetween, and connected to form a desired path by a contact via 234. The wiring layer 236 or the contact via 234 may include various conductive materials, and the first insulation layer 232 may include various insulating materials.

A contact region 104 and a second wiring portion 180 may be provided to connect the gate stacking structure 120 and the channel structure CH provided in the cell array region 102 to the circuit region 200 or an external circuit.

The second wiring portion 180 may include all the members that electrically connect the plurality of gate electrodes 130, the channel structure CH, and/or the second substrate 110 to the circuit region 200 or to the external circuit. For example, the second wiring portion 180 may include a bit line 182, a gate contact portion 184, a source contact portion 186, a through-hole plug 188, a contact via 180a connected to each of the bit line 182, the gate contact portion 184, the source contact portion 186, and the through-hole plug 188, and a connection wire 190 connecting the bit line 182, the gate contact portion 184, the source contact portion 186, and the through-hole plug 188.

The bit line 182 may be disposed on the cell insulation layer 132 of the gate stacking structure 120 formed in the cell array region 102. The bit line 182 may extend in the second direction (Y direction). The bit line 182 may be electrically connected to the channel structure CH, for example, the channel pad 144, via the contact via 180a, for example, a bit line contact via.

The contact region 104 may be disposed at the periphery of the cell array region 102. A part of the second wiring portion 180 may be disposed in the contact region 104. The contact region 104 may include a gate contact portion 184 for connecting the gate stacking structure 120 disposed on the second substrate 110 and the plurality of gate electrodes 130 of the cell array region 102 to the circuit region 200 or the external circuit.

The plurality of gate electrodes 130 may be extended in the first direction (X direction) and disposed in the contact region 104, and an extension length of the plurality of gate electrodes 130 in the contact region 104 may sequentially decrease as the gate electrode gets farther away from the second substrate 110. For example, a plurality of gate electrodes 130 may be disposed in the contact region 104 with a step shape. In such a case, the plurality of gate electrodes 130 may have the step shape in one direction or in a plurality of directions. In the contact region 104, the plurality of gate contact portions 184 may penetrate the cell insulation layer 132, and thus may be electrically connected to the plurality of gate electrodes 130 extending to the contact region 104.

In addition, in the contact region 104, the source contact portion 186 may penetrate the cell insulation layer 132, and thus may be electrically connected with the second substrate 110. For example, the source contact portion 186 may penetrate the second horizontal conductive layer 114 and the horizontal insulation layer 116, and thus may be electrically connected with the second substrate 110.

The through-hole plug 188 may pass through the gate stacking structure 120 or be disposed outside the gate stacking structure 120 and be electrically connected to the first wiring portion 230 of the circuit region 200. However, the present disclosure is not limited in this regard. For example, the through-hole plug 188 may pass through the gate stacking structure 120 and be electrically connected to the first wiring portion 230 of the circuit region 200.

A connection wire 190 may be disposed in the cell array region 102 and/or the contact region 104. The bit line 182, the gate contact portion 184, the source contact portion 186, and/or the through-hole plug 188 may be electrically connected to the connection wire 190. For example, the gate contact portion 184, the source contact portion 186, and/or the through-hole plug 188 may be connected to the connection wire 190 through the contact via 180a.

Although FIG. 1 illustrates the connection wire 190 as a single layer disposed on the same plane as the bit line 182, and the second insulation layer 192 disposed on a portion other than the second wiring portion 180, the present disclosure is not limited in this regard. That is, the illustrated structure is only a simplified illustration for the sake of convenience. Thus, the connection wire 190 may include a plurality of wiring layers for electrical connection with the bit line 182, the gate contact portion 184, the source contact portion 186, and/or the through-hole plug 188, and may further include a contact via. Consequently, the bit line 182, the plurality of gate electrodes 130, and/or second substrate 110 the plurality of gate electrodes 130 and/or the second substrate 110 connected to the channel structure CH may be electrically connected to the circuit element 220 of the circuit region 200 by the second wiring portion 180 and the first wiring portion 230.

Although FIG. 1 illustrates the gate contact portion 184, the source contact portion 186, and/or the through-hole plug 188 as having inclined side surfaces of which widths become narrower as they get closer to the second substrate 110 according to the aspect ratio when viewed on a cross-section, and a bend portion as being provided at the boundary between the first gate stacking structure 120a and the second gate stacking structure 120b, the present disclosure is not limited in this regard. For example, the gate contact portion 184, the source contact portion 186, and/or the through-hole plug 188 may not have a bend portion at the boundary between the first gate stacking structure 120a and the second gate stacking structure 120b.

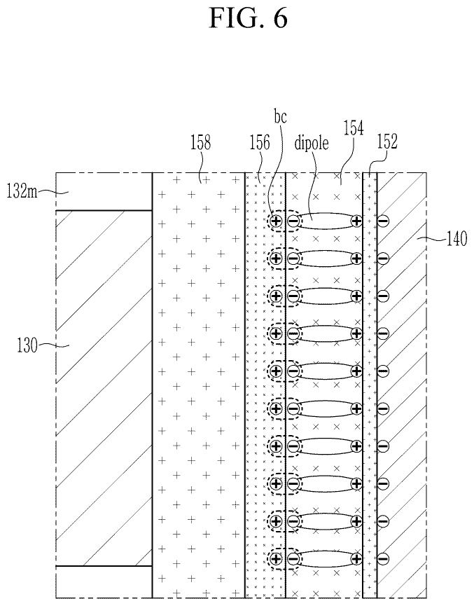

FIG. 6 is an enlarged cross-sectional view of the region B of FIG. 5, according to an embodiment. FIG. 6 illustrates a detailed description of the bound charge layer 156 of the semiconductor device, according to the embodiment. That is, FIG. 6 is a cross-sectional view illustrating the dielectric layer 150 when the electric field applied between the gate electrode 130 and the channel layer 140 for the program operation is removed after the program operation of the semiconductor device is performed, according to the embodiment.

During the program operation, a positive voltage may be applied to the gate electrode 130. In such a case, the positive and negative charges included in the ferroelectric layer 154 may be aligned in a certain direction to form a plurality of dipoles by the voltage applied between the gate electrode 130 and the channel layer 140. For example, as shown in FIG. 6, in the case of the program operation of the semiconductor device, the dipoles included in the ferroelectric layer 154 may be arranged such that the positive charge may be arranged to be adjacent to the channel layer 140 and the negative charge may be arranged to be adjacent to the gate electrode 130. At least some regions of the ferroelectric layer 154 may be polarized due to the dipoles arranged in a certain direction. For example, referring to FIG. 6, among the entire region of the ferroelectric layer 154, a region that overlaps the gate electrode 130 in the horizontal direction may have a polarized state. The ferroelectric layer 154 may maintain the polarized state due to residual polarization even after the voltage applied between the gate electrode 130 and the channel layer 140 is removed. The residual polarization may be caused due to the ferroelectric characteristic of a ferroelectric material, and may be a polarization that may remain within the ferroelectric layer 154 even after the electric field due to the voltage applied between the gate electrode 130 and the channel layer 140 disappears (e.g., is removed) during the operation of the semiconductor device.

The bound charge layer 156 included in the semiconductor device, according to the embodiment, may include a plurality of bound charges bc disposed at the interface with the ferroelectric layer 154. The bound charges bc may flow into the bound charge layer 156 during a write or erase operation of the semiconductor device. For example, referring to FIG. 6, in the program operation of the semiconductor device, the bound charges bc may be inflowed from the gate electrode 130 through the tunneling insulation layer 158 into the bound charge layer 156 by a voltage applied to the gate electrode 130.

The bound charges bc that flow into the bound charge layer 156 may be combined with polarization charges that may be included in the ferroelectric layer 154 and may have opposite polarity to the bound charges at the interface between the ferroelectric layer 154 and the bound charge layer 156, thereby compensating for the polarization charges. For example, referring to FIG. 6, positive charges flown into the bound charge layer 156 in the program operation of a semiconductor device may be combined with negative charges of the ferroelectric layer 154 at the interface between the ferroelectric layer 154 and the bound charge layer 156. The bound charges bc may remain the combined state with the negative charges of the ferroelectric layer 154 due to residual polarization even after the voltage applied between the gate electrode 130 and the channel layer 140 is removed, and thus may be bound to the bound charge layer 156.

When the polarization charges disposed on the surface of the ferroelectric layer 154 are not compensated, the residual polarization formed in the ferroelectric layer 154 may be depolarized by a depolarization field that may exist inside the ferroelectric layer 154.

In the semiconductor device, such as that described with reference to FIGS. 1 to 5, the larger the size of the residual polarization, the larger the memory window of the semiconductor device may have. In the case of the semiconductor device, according to the embodiment, depolarization of the residual polarization formed in the ferroelectric layer 154 may be prevented and/or reduced by effectively compensating for polarization charges, and thus a wide range of memory windows may be achieved.

In addition, since the bound charges bc are effectively bound within the bound charge layer 156, a threshold voltage shift phenomenon that may occur as the charges within the insulation layer disposed between the gate electrode 130 and the ferroelectric layer 154 move toward the gate electrode 130 and/or the ferroelectric layer 154 may be improved.

FIG. 6 illustrates the program operation of the semiconductor device as an example, but the dipoles may be arranged in the opposite direction to that shown in FIG. 6 in an erase operation. In such a case, the negative charges may be bound to the bound charge layer 156. Even in the case of the erase operation, the effect of the bound charge layer 156 including bound charges bc may be similar to that of the program operation, and therefore a detailed description thereof may be omitted for the sake of brevity.

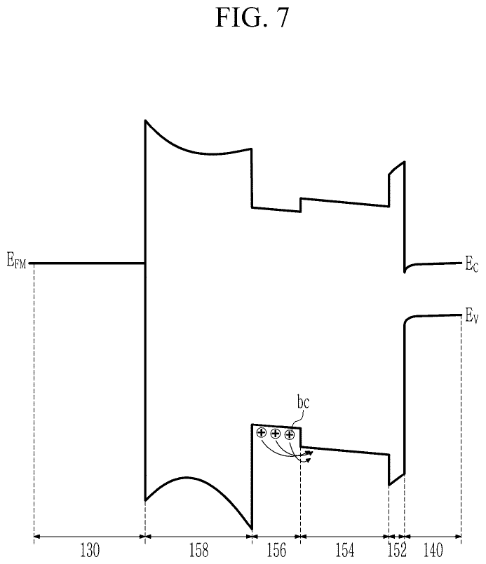

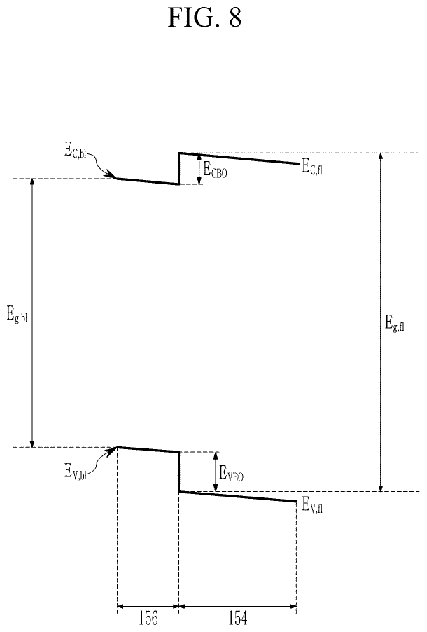

FIGS. 7 and 8 illustrate a conduction band offset and a valence band offset between the bound charge layer 156 and the ferroelectric layer 154. For example, FIG. 7 is an energy band diagram that shows energy bands according to position in the region B of FIG. 5, and FIG. 8 is an energy band diagram that shows energy bands according to position of the bound charge layer and the ferroelectric layer, according to the embodiment.

FIGS. 7 and 8 may show energy band diagrams after a program voltage is provided between the gate electrode 130 and the channel layer 140 and then the program voltage is removed in the program operation of the semiconductor device, according to the embodiment. FIG. 7 may sequentially show a fermi level EFM of the gate electrode 130, and a conduction band energy level E_{C} and a valence band energy level E_{V} of the tunneling insulation layer 158, the bound charge layer 156, the ferroelectric layer 154, the channel insulation layer 152, and the channel layer 140. FIG. 8 may sequentially show a conduction band energy level E_{C,bl} and a valence band energy level E_{V,bl} of the bound charge layer 156, and a conduction band energy level E_{C,fl} and a valence band energy level E_{V,fl} of the ferroelectric layer 154.

As used herein, the conduction band energy level (E_{C}, E_{C,bl}, and E_{C,fl}) may refer to an energy level having the smallest value among the energy levels included in the conduction band, and the valence band energy level (E_{V}, E_{V,bl}, and E_{V,fl}) may refer to an energy level having the largest value among the energy levels included in the valence band. Referring to FIG. 8, the energy bandgap E_{g,bl} of the bound charge layer 156, according to the embodiment, may be defined by the conduction band energy level E_{C,bl} and the valence band energy level E_{V,bl} of the bound charge layer 156. The energy bandgap E_{g,fl} of the ferroelectric layer 154, according to the embodiment, may be defined by the conduction band energy level E_{C,fl} and the valence band energy level E_{V,fl} of the ferroelectric layer 154.

The semiconductor device, according to the embodiment, may have a conduction band offset E_{CBO} of a predetermined size based on the conduction band energy level E_{C,bl} of the bound charge layer 156 and the conduction band energy level E_{C,fl} of the ferroelectric layer 154. As used herein, the conduction band offset E_{CBO} may refer to a value obtained by subtracting the conduction band energy level E_{C,bl} of the bound charge layer 156 from the conduction band energy level E_{C,fl} of the ferroelectric layer 154.

The semiconductor device, according to the embodiment, may have a valence band offset E_{VBO} of a predetermined size based on the valence band energy level E_{V,bl} of the bound charge layer 156 and the valence band energy level E_{V,fl} of the ferroelectric layer 154. As used herein, the valence band offset E_{VBO} may refer to a value obtained by subtracting the valence band energy level E_{V,bl} of the ferroelectric layer 154 from the valence band energy level E_{V,fl} of the bound charge layer 156.

Referring to FIG. 7 and FIGS. 8, during the program operation of the semiconductor device, bound charges bc flown into the bound charge layer 156 may occupy either the valence band energy level E_{V,bl} of the bound charge layer 156 or any one of the adjacent energy levels. In such a case, the bound charges bc occupying energy levels included in the valence of bound charge layer 156 may be positive charges (e.g., holes). When the valence band offset E_{VBO} between the bound charge layer 156 and the ferroelectric layer 154 is relatively very low, at least some of the bound charges bc may cross a potential barrier between the bound charge layer 156 and the ferroelectric layer 154 and migrate into the ferroelectric layer 154.

In the case of an erase operation of the semiconductor device, according to the embodiment, the bound charges bc flown into the bound charge layer 156 may occupy either the conduction band energy level E_{C,bl} of the bound charge layer 156 or one of its adjacent energy levels. In such a case, the bound charges bc occupying energy levels included in the conduction band of bound charge layer 156 may be negative charges (e.g., electrons). When the conduction band offset E_{CBO} between the bound charge layer 156 and the ferroelectric layer 154 is relatively very low, at least some of the bound charges bc may cross the potential barrier between the bound charge layer 156 and the ferroelectric layer 154 and migrate into the ferroelectric layer 154.

As described above, when the bound charges bc move from the bound charge layer 156 to the ferroelectric layer 154, the number of polarization charges not compensated by the bound charges bc within the ferroelectric layer 154 may increase. In such a case, residual polarization formed in the ferroelectric layer 154 may be depolarized, which may reduce the memory window of the semiconductor device, according to the embodiment. In addition, in this case, as the bound charges bc move from the bound charge layer 156 to the ferroelectric layer 154, a threshold voltage of the semiconductor device may shift, and thus the reliability of the semiconductor device may be deteriorated.

The bound charge layer 156 of the semiconductor device, according to the embodiment, may be designed to include an insulating material having an appropriate size of conduction band energy level E_{C} and valence band energy level E_{V} to effectively bind the bound charges bc to the bound charge layer 156.

For example, the insulating material included in the bound charge layer 156, according to the embodiment, may be selected as an insulating material in which at least one of the conduction band energy level E_{C} and the valence band energy level E_{V} is disposed between the conduction band energy level E_{C,fl} and the valence band energy level E_{V,fl} of the ferroelectric layer 154.

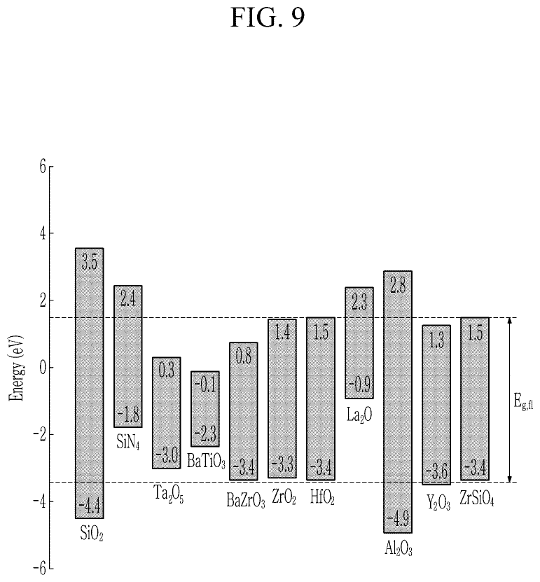

FIG. 9 shows a comparison between the energy bandgap of insulating materials and the energy bandgap of ferroelectric materials, according to an embodiment. For example, FIG. 9 illustrates the energy bandgap of hafnium oxide (HfO₂), which is one of the ferroelectric materials described with reference to FIGS. 1 to 4 is compared with energy bandgaps of various insulating materials. However, hafnium oxide (HfO₂) is selected as an example, and in another embodiment, other materials than hafnium oxide (HfO₂) may be selected from among various ferroelectric materials described with reference to FIGS. 1 to 4.

In the embodiment, an insulating material that has an energy bandgap smaller than the energy bandgap E_{g,fl} of the ferroelectric layer 154, and also has a conduction band offset E_{CBO} and a valence band offset E_{VBO} that are positive may be selected as the insulating material to be included in the bound charge layer 156. For example, the energy bandgap of the insulating material included in the bound charge layer 156 may have a value smaller than about 6 eV. As another example, the insulating material included in the bound charge layer 156, according to the embodiment of FIG. 9, may include at least one of tantalum oxide (Ta₂O₅) or barium titanium oxide (BaTiO₃).

In the embodiment, an insulating material having a negative conduction band offset E_{CBO} and a positive valence band offset E_{VBO} may be selected as the insulating material included in the bound charge layer 156. That is, an insulating material of which the conduction band energy level E_{C} is greater than or equal to the conduction band energy level E_{C,fl} of the ferroelectric layer 154 and the valence band energy level E_{V} is greater than the valence band energy level E_{V,fl} of the ferroelectric layer 154 may be selected. For example, referring to FIG. 9, the insulating material included in the bound charge layer 156, according to the embodiment, may include, but not be limited to, lanthanum oxide (La₂O₃). Alternatively or additionally, the insulating material included in the bound charge layer 156 may include at least one of gallium oxide (Ga₂O₃) and aluminum oxynitride (AlON).

In the embodiment, an insulating material that has a conduction band offset E_{CBO} with a positive value and a valence band offset E_{VBO} with a negative value may be selected as the insulating material included in the bound charge layer 156. That is, an insulating material in which the conduction band energy level E_{C} is smaller than the conduction band energy level E_{C,fl} of the ferroelectric layer 154 and the valence band energy level E_{V} is smaller than or equal to the valence band energy level E_{V,fl} of the ferroelectric layer 154 may be selected. For example, referring to FIG. 9, the insulating material included in the bound charge layer may include, but not be limited to, yttrium oxide (Y₂O₃) and barium zirconium oxide (BaZrO₃).

In the embodiment, the bound charge layer 156 may not include silicon nitride (SiNₓ). When the bound charge layer 156 includes silicon nitride (SiNₓ), charges that flow into the bound charge layer 156 may be trapped by trap centers within a membrane rather than being combined to polarizing charges. The charges trapped inside the bound charge layer 156 may easily escape to the ferroelectric layer 154 compared to the bound charge bc, and as a result, the threshold voltage of the semiconductor device may shift, which may deteriorate the reliability of the semiconductor device.

An electronic system including a semiconductor device, according to an embodiment, is described with reference to FIG. 10.

FIG. 10 schematically shows an electronic system including a semiconductor device, according to an embodiment.

As shown in FIG. 10, an electronic system 1000, according to an embodiment, may include a semiconductor device 1100 and a controller 1200 electrically connected with the semiconductor device 1100. The electronic system 1000 may be a storage device including one or a plurality of semiconductor devices 1100 or an electronic device including the storage device. For example, the electronic system 1000 may be a solid state drive device (SSD), a universal serial bus (USB), a computing system, a medical device, or a communication apparatus including one or a plurality of semiconductor devices 1100.

The semiconductor device 1100 may be and/or may include a non-volatile memory device, and for example, the semiconductor device 1100 may be and/or may include a NAND flash memory device similar in many respects to the semiconductor device 10 described with reference to FIGS. 1 to 9. The semiconductor device 1100 may include a first structure 1100F and a second structure 1100S on the first structure 1100F. In an embodiment, the first structure 1100F may be placed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, a first gate upper line UL1 and a second gate upper line UL2, a first gate lower line LL1 and the second gate lower line LL2, and a memory cell string CSTR between the bit line BL and the common source line CSL.

In the second structure 1100S, each memory cell string CSTR may include lower transistors (e.g., a first lower transistor LT1 and a second lower transistor LT2) that may be adjacent to the common source line CSL, upper transistors (e.g., a first upper transistor UT1 and a second upper transistor UT2) that may be adjacent to the bit line BL, and a plurality of memory cell transistors MCT disposed between the first and second lower transistors LT1 and LT2 and the first and second upper transistors UT1 and UT2. The number of lower transistors and the number of upper transistors may vary depending on embodiments.

In an embodiment, the first and second lower transistors LT1 and LT2 may include a ground selection transistor, and the first and second upper transistors UT1 and UT2 may include a string selection transistor. The first gate lower line LL1 and the second gate lower line LL2 may be gate electrodes of the first and second lower transistors LT1 and LT2, respectively. The word line WL may be a gate electrode of a memory cell transistor MCT, and the first and second gate upper lines UL1 and UL2 may be gate electrodes of the first and second upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wire 1115 extending to the second structure 1100S from the first structure 1100F. The bit line BL may be electrically connected to the page buffer 1120 through a second connection wire 1125 that may extend from the first structure 1100F to the second structure 1100S.

In the first structure 1100F, the decoder circuit 1110 and the page buffer 1120 may perform control operations on at least one memory cell transistor selected from a plurality of memory cell transistors MCT. The decoder circuit 1110 and the page buffer 1120 may be controlled by the logic circuit 1130. The semiconductor device 1100 may communicate with the controller 1200 through an input/output pad 1101 that may be electrically connected with the logic circuit 1130. The input/output pad 1101 may be electrically connected to the logic circuit 1130 via an input/output connection wire 1135 that extends from the first structure 1100F to the second structure 1100S.

The controller 1200 may include a processor 1210, a NAND controller 1220, and a host interface 1230. Depending on embodiments, the electronic system 1000 may include a plurality of semiconductor devices 1100, and in this case, the controller 1200 may control the plurality of semiconductor devices 1100.

The processor 1210 may control the operation of the entire electronic system 1000, including the controller 1200. The processor 1210 may operate according to predetermined firmware and control the NAND controller 1220 to access the semiconductor device 1100. The NAND controller 1220 may include a NAND interface 1221 that handles communications with the semiconductor device 1100. Through the NAND interface 1221, control instructions for controlling the semiconductor device 1100, data to be written to the memory cell transistor MCT of the semiconductor device 1100, data to be read from the memory cell transistor MCT of the semiconductor device 1100, or the like may be transmitted. The host interface 1230 may provide a communication function between the electronic system 1000 and an external host. When receiving a control instruction from an external host through the host interface 1230, the processor 1210 may respond to the control instruction and control the semiconductor device 1100.

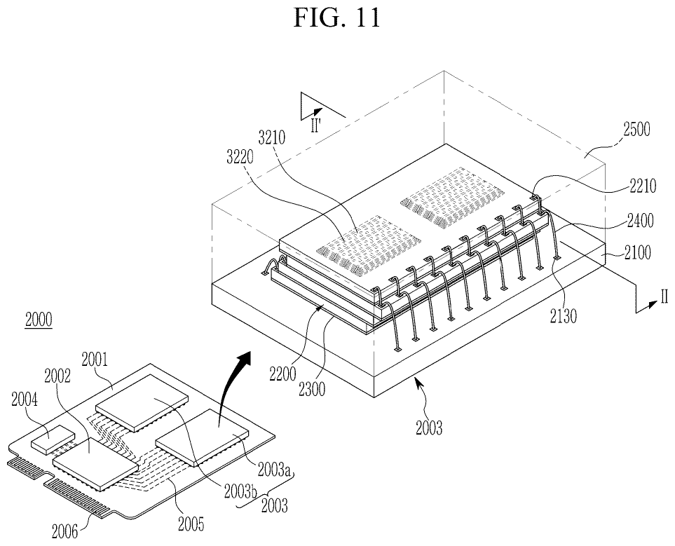

FIG. 11 is a schematic perspective view of an electronic system including a semiconductor, according to an embodiment.

As shown in FIG. 11, an electronic system 2000, according to an embodiment, may include a main substrate 2001, a controller 2002 mounted on the main substrate 2001, one or more semiconductor packages 2003, and a DRAM 2004. The semiconductor package 2003 and the DRAM 2004 may be interconnected with the controller 2002 by a wiring pattern 2005 formed on the main substrate 2001.

The main substrate 2001 may include a connector 2006 having a plurality of pins that may be coupled to an external host. The number and arrangement of pins in the connector 2006 may vary depending on a communication interface between the electronic system 2000 and an external host. In an embodiment, the electronic system 2000 may communicate with an external host according to any one of the following interfaces: universal serial bus (USB), peripheral component interconnect express (PCI-Express), serial advanced technology attachment (SATA), or M-Phy for universal flash storage (UFS). In an embodiment, the electronic system 2000 may be powered by power supplied from an external host via the connector 2006. The electronic system 2000 may further include a power management integrated circuit (PMIC) that may distribute power supplied from an external host to the controller 2002 and the semiconductor package 2003.

The controller 2002 may write data to the semiconductor package 2003 and/or read data from the semiconductor package 2003, and may improve the operation speed of the electronic system 2000.

The DRAM 2004 may be a buffer memory that may alleviate a speed difference between the semiconductor package 2003, which may be and/or may include a data storage space, and the external host. The DRAM 2004 included in the electronic system 2000 may also function in a similar manner to a cache memory and provide a space to temporarily store data in control operations for the semiconductor package 2003. When the electronic system 2000 includes the DRAM 2004, the controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b, which may be spaced apart from each other. The first semiconductor package 2003a and the second semiconductor package 2003b may each be a semiconductor package including a plurality of semiconductor chips 2200. Each of the first semiconductor package 2003a and the second semiconductor package 2003b may include a package substrate 2100, the semiconductor chip 2200 on the package substrate 2100, an adhesive layer 2300 disposed on a bottom surface of each of the semiconductor chips 2200, a connection structure 2400 electrically connecting the semiconductor chip 2200 and the package substrate 2100, and a molding layer 2500 that covers the semiconductor chip 2200 and the connection structure 2400 on the package substrate 2100.

The package substrate 2100 may be a printed circuit board including the package upper pad 2130. Each semiconductor chip 2200 may include an input/output pad 2210. The input/output pad 2210 may correspond to the input/output pad 1101 of FIG. 10. Each semiconductor chip 2200 may include a gate stacking structure 3210 and a channel structure 3220. The semiconductor chip 2200 may include a semiconductor device that may include and/or may be similar in many respects to the semiconductor device 10 described with reference to FIGS. 1 to 9.

In an embodiment, the connection structure 2400 may be and/or may include a bonding wire that may electrically connect the input/output pad 2210 and the package upper pad 2130. Therefore, in each of the first semiconductor package 2003a and the second semiconductor package 2003b, the semiconductor chips 2200 may be electrically connected to each other in a bonding wiring manner and may be electrically connected to the package upper pad 2130 of the package substrate 2100. Depending on embodiments, in each of the first semiconductor package 2003a and the second semiconductor package 2003b, the semiconductor chips 2200 may be electrically connected to each other by a connection structure including a through silicon via (TSV), instead of the bonding wire-type connection structure 2400.

In an embodiment, the controller 2002 and the semiconductor chip 2200 may be included in one package. For example, the controller 2002 and the semiconductor chip 2200 may be mounted on a separate interposer substrate from the main substrate 2001, and the controller 2002 and the semiconductor chip 2200 may be connected to each other by wiring formed on the interposer substrate.

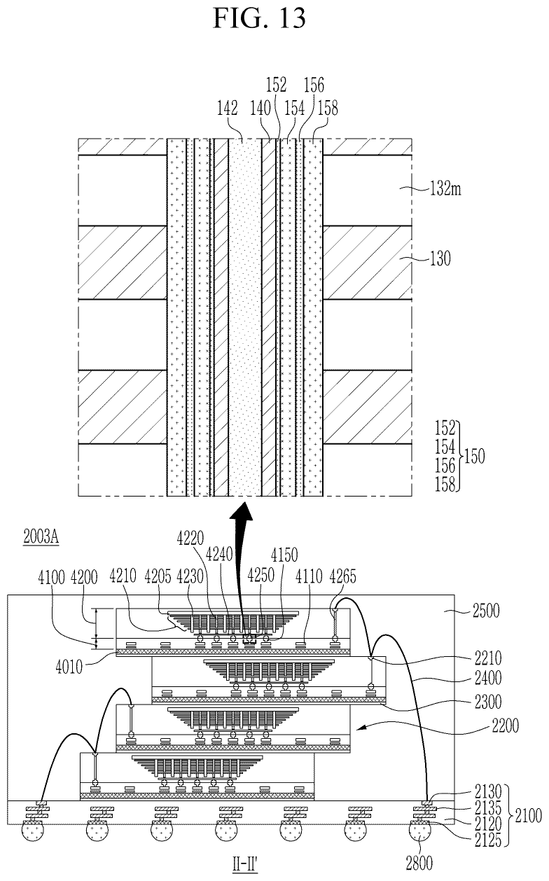

FIGS. 12 and 13 are schematic cross-sectional views of semiconductor packages, according to embodiments, respectively. FIGS. 12 and 13 illustrate embodiments of the semiconductor package 2003 of FIG. 11, and conceptually show the region cut along the cutting line II-II′ of the semiconductor package 2003 of FIG. 11.

Referring to FIG. 12, in the semiconductor package 2003, a package substrate 2100 may be and/or may include a printed circuit board (PCB). The package substrate 2100 may include a package substrate body portion 2120, a package upper pad 2130 disposed on an upper surface of the package substrate body portion 2120, a lower pad 2125 that may be disposed on a bottom surface of the package substrate body portion 2120 and/or may extend through the bottom surface, and an inner wire 2135 that may electrically connected the upper pad 2130 and the lower pad 2125 in the package substrate body portion 2120. The upper pad 2130 may be electrically connected with the connection structure 2400. The lower pad 2125 may be connected to a wiring pattern 2005 of the main substrate 2001 of the electronic system 2000, as shown in FIG. 11, via a conductive connection 2800.

The semiconductor chip 2200 may each include a semiconductor substrate 3010 and a first structure 3100 and a second structure 3200 sequentially stacked on the semiconductor substrate 3010. The first structure 3100 may include a peripheral circuit region including a peripheral wire 3110. The second structure 3200 may include a common source line 3205, a gate stacking structure 3210 on the common source line 3205, a channel structure 3220 and a separation structure 3230 that penetrate the gate stacking structure 3210, a bit line 3240 electrically connected with the channel structure 3220, and a gate connection wire that is electrically connected with a word line (e.g., word line WL of FIG. 10) of the gate stacking structure 3210.

In the semiconductor chip 2200 and/or the semiconductor device 10, according to the embodiment, a bound charge layer 156 may be disposed between the gate electrode 130 and the ferroelectric layer 154, and the bound charge layer 156 may include a plurality of bound charges bc. The bound charges bc included in the bound charge layer 156 may compensate for polarization charges, and may reduce and/or prevent depolarization of residual polarization formed in the ferroelectric layer 154, and accordingly the semiconductor device, according to the embodiment, may have a memory window of a relatively wide range, when compared to related semiconductor devices. In addition, since the bound charges bc may be effectively bound within the bound charge layer 156, a threshold voltage shift phenomenon that may occur as the charges within the insulation layer disposed between the gate electrode 130 and the ferroelectric layer 154 move toward the gate electrode 130 and/or the ferroelectric layer 154 may be improved, when compared to related semiconductor devices.

A charge inflow pattern 310 may be disposed on one side of the ferroelectric layer 154, and an insulation pattern 320 may surround at least a portion of the charge inflow pattern 310. Accordingly, when a voltage is applied to a plurality of gate electrodes 130, an electric field may be generated within the charge inflow pattern 310 depending on a dopant concentration. Accordingly, an operation voltage at which the residual polarization of the ferroelectric layer 154 is generated may be improved, and the reliability of the semiconductor device 10 may be improved, when compared to related semiconductor devices.

Each of the semiconductor chips 2200 may include a through-hole wire 3245 that may be electrically connected with the peripheral wire 3110 of the first structure 3100 and may extend into the second structure 3200. The through-hole wire 3245 may penetrate the gate stacking structure 3210, and may be placed further on the outside of the gate stacking structure 3210. Each semiconductor chip 2200 may further include an input/output connection wire 3265 electrically connected with the peripheral wire 3110 of the first structure 3100 and extending into the second structure 3200, and an input/output pad 2210 electrically connected with the input/output connection wire 3265.

In an embodiment, in the semiconductor package2003, a plurality of semiconductor chips 2200 may be electrically connected to each other by a connection structure 2400 in the form of bonding wires. As another example, a plurality of semiconductor chip 2200 and/or a plurality of parts forming the same may be electrically connected by a connection structure including a through silicon via (TSV).

Referring to FIG. 13, in a semiconductor package 2003A, each semiconductor chip 2200 may include a semiconductor substrate 4010, a first structure 4100 on the semiconductor substrate 4010, and a second structure 4200 bonded to the first structure 4100 by a wafer bonding method on the first structure 4100.

The first structure 4100 may include a peripheral circuit region including a peripheral wire 4110 and a first bonding structure 4150. The second structure 4200 may include a common source line 4205, a gate stacking structure 4210 between the common source line 4205 and the first structure 4100, a channel structure 4220 and a separation structure 4230 penetrating the gate stacking structure 4210, and a second bonding structure 4250 that may be electrically connected with the channel structure 4220 and a word line (e.g., word line WL of FIG. 10) of the gate stacking structure 4210. For example, the second bonding structure 4250 may be electrically connected with the channel structure 4220 and the word line WL respectively through a bit line 4240 electrically connected with the channel structure 4220 and a gate connection wire electrically connected with the word line WL. The first bonding structure 4150 of the first structure 4100 and the second bonding structure 4250 of the second structure 4200 may be bonded with each other while being in contact with each other. A bonded portion of the first bonding structure 4150 and the second bonding structure 4250 may be formed of, for example, copper (Cu).

In the semiconductor chip 2200 or the semiconductor device 10, according to the embodiment, a bound charge layer 156 may be disposed between the gate electrode 130 and the ferroelectric layer 154 and the bound charge layer 156 may include a plurality of bound charges bc. The bound charges bc included in the bound charge layer 156 may compensate for polarization charges, and may reduce and/or prevent depolarization of residual polarization formed in the ferroelectric layer 154, and accordingly the semiconductor device, according to the embodiment, may have a memory window of a relatively wide range, when compared to related semiconductor devices. In addition, since the bound charges bc may be effectively bound within the bound charge layer 156, a threshold voltage shift phenomenon that may occur as the charges within the insulation layer disposed between the gate electrode 130 and the ferroelectric layer 154 move toward the gate electrode 130 and/or the ferroelectric layer 154 may be improved, when compared to related semiconductor devices.

Each semiconductor chip 2200 may further include an input/output pad 2210 and an input/output connection wire 4265 under the input/output pad 2210. The input/output connection wire 4265 may be electrically connected to some of the second bonding structure 4250.

In an embodiment, in the semiconductor package 2003A, a plurality of semiconductor chips 2200 may be electrically connected to each other by a connection structure 2400 in the form of bonding wires. As another example, a plurality of semiconductor chip 2200 and/or a plurality of parts forming the same may be electrically connected by a connection structure including a through silicon via.

While this disclosure has been described in connection with what is presently considered to be practical embodiments, it is to be understood that the present disclosure is not limited to the disclosed embodiments. On the contrary, the present disclosure is intended to cover various modifications and equivalent arrangements included within the spirit and scope of the appended claims.

What is claimed is:

1. A semiconductor device, the semiconductor device comprising:
a substrate;
a gate stacking structure comprising a plurality of interlayer insulating layers and a plurality of gate electrodes alternately stacked on the substrate; and
a channel structure at least partially penetrating the gate stacking structure, extending in one direction, and comprising:
a channel layer coupled with the substrate;
a ferroelectric layer at least partially surrounding the channel layer and comprising a ferroelectric material; and
a bound charge layer at least partially surrounding the ferroelectric material and comprising an insulating material,
wherein at least one of a conduction band energy level or a valence band energy level of the insulating material is disposed between a conduction band energy level and a valence band energy level of the ferroelectric material.

2. The semiconductor device of claim 1, wherein an energy bandgap of the insulating material is smaller than an energy bandgap of the ferroelectric material.

3. The semiconductor device of claim 2, wherein the insulating material contains at least one of tantalum oxide (Ta₂O₅) or barium titanium oxide (BaTiO₃).

4. The semiconductor device of claim 1, wherein a valence band energy level of the insulating material is greater than a valence band energy level of the ferroelectric material, and
wherein a conduction band energy level of the insulating material is greater than or equal to a conduction band energy level of the ferroelectric material.

5. The semiconductor device of claim 4, wherein the insulating material comprises at least one of gallium oxide (Ga₂O₃) or lanthanum oxide (La₂O₃).

6. The semiconductor device of claim 1, wherein a conduction band energy level of the insulating material is smaller than a conduction band energy level of the ferroelectric material, and
wherein a valence band energy level of the insulating material r is smaller than or equal to a valence band energy level of the ferroelectric material.

7. The semiconductor device of claim 6, wherein the insulating material comprises at least one of yttrium oxide (Y₂O₃) or barium-zirconium oxide (BaZrO₃).

8. The semiconductor device of claim 1, further comprising:
a channel insulation layer at least partially surrounding the channel layer and disposed between the channel layer and the ferroelectric layer; and
a tunneling insulation layer at least partially surrounding the bound charge layer and disposed between the bound charge layer and the plurality of gate electrodes.

9. The semiconductor device of claim 8, wherein the tunneling insulation layer comprises at least one of silicon oxide (SiO₂) or silicon oxynitride (SiON).

10. The semiconductor device of claim 8, wherein the channel insulation layer comprises at least one of silicon oxide (SiO₂), silicon oxynitride (SiON), aluminum oxynitride (AlON), hafnium oxynitride (HfON), aluminum oxide (Al₂O₃), or carbon (C) doped silicon oxide (SiO₂).

11. The semiconductor device of claim 1, wherein a side surface of the bound charge layer is in contact with the ferroelectric layer.

12. The semiconductor device of claim 1, wherein the bound charge layer comprises a plurality of charges that are bound in a region adjacent to an interface with the ferroelectric layer.

13. The semiconductor device of claim 1, wherein the ferroelectric material contains at least one of hafnium oxide (HfO₂), hafnium zirconium oxide (HfₓZr₁₋ₓO₂), barium titanium oxide (BaTiO₃), and aluminum scandium nitride (AlScN).

14. A semiconductor device, the semiconductor device comprising:
a substrate;
a gate stacking structure comprising a plurality of interlayer insulating layers and a plurality of gate electrodes alternately stacked on the substrate; and
a channel structure at least partially penetrating the gate stacking structure, extending in one direction, and comprising:
a channel layer coupled with the substrate;
a ferroelectric layer at least partially surrounding the channel layer and comprising a ferroelectric material; and
a bound charge layer at least partially surrounding the ferroelectric material and comprising an insulating material,
wherein a side surface of the bound charge layer is in contact with the ferroelectric layer, and
wherein the bound charge layer comprises a plurality of charges bound to a region adjacent to an interface with the ferroelectric layer.

15. The semiconductor device of claim 8, wherein at least one of a conduction band energy level or a valence band energy level of the insulating material is disposed between a conduction band energy level and a valence band energy level of the ferroelectric material.

16. The semiconductor device of claim 14, wherein an energy bandgap of the insulating material is smaller than an energy bandgap of the ferroelectric material.

17. The semiconductor device of claim 14, further comprising:
a channel insulation layer at least partially surrounding the channel layer and disposed between the channel layer and the ferroelectric layer; and
a tunneling insulation layer at least partially surrounding the bound charge layer and disposed between the bound charge layer and the plurality of gate electrodes.

18. An electronic system, the electronic system comprising:
a main substrate;
a semiconductor device on the main substrate; and
a controller electrically coupled with the semiconductor device on the main substrate,
wherein the semiconductor device comprises:
a peripheral circuit region;
a cell region comprising an input/output connection wire electrically coupled with the peripheral circuit region; and
an input/output pad electrically coupled with the input/output connection wire extending into the cell region,
wherein the cell region comprises:
a substrate;
a gate stacking structure comprising a plurality of interlayer insulating layers and a plurality of gate electrodes alternately stacked on the substrate;
a channel structure at least partially penetrating the gate stacking structure, extending in one direction, and comprising:
a channel layer coupled with the substrate;
a ferroelectric layer at least partially surrounding the channel layer and comprising a ferroelectric material; and
a bound charge layer at least partially surrounding the ferroelectric material and comprising an insulating material, and
wherein at least one of a conduction band energy level or a valence band energy level of the insulating material is disposed between a conduction band energy level and a valence band energy level of the ferroelectric material.

19. The electronic system of claim 18, wherein an energy bandgap of the insulating material is smaller than an energy bandgap of the ferroelectric material.

20. The electronic system of claim 18, wherein a side surface of the bound charge layer is in contact with the ferroelectric layer, and
wherein the bound charge layer comprises a plurality of charges that are bound in a region adjacent to an interface with the ferroelectric layer.
